(19) United States
(12) Patent Application Publication
(10) Pub. No.: US 2026/0165107 A1
(43) Pub. Date: Jun. 11, 2026

(54) SEMICONDUCTOR STRUCTURE AND METHOD FOR FORMING THE SAME

(71) Applicant: WIN SEMICONDUCTORS CORP., TAOYUAN CITY (TW)

(72) Inventors: Chang-Hwang HUA, TAOYUAN CITY (TW); Yao-Ren LIANG, TAOYUAN CITY (TW); Chia-Jun YANG, TAOYUAN CITY (TW)

(21) Appl. No.: 18/975,639

(22) Filed: Dec. 10, 2024

(51) Int. Cl. H01L 23/532; H01L 21/768; H01L 23/48; H01L 23/522; H01L 23/528; H10D 62/13; H10D 64/00; H10D 84/01

(52) U.S. Cl. CPC H10W 20/425; H10D 62/151; H10D 64/111; H10D 84/013; H10W 20/056; H10W 20/20; H10W 20/42; H10W 20/43

(57) ABSTRACT

A semiconductor device includes a substrate having a first surface and a second surface. The device also includes a metal stack disposed on the first surface. The metal stack includes a plurality of adhesion layers and at least one resistant layer alternately stacked. The device also includes an opening formed within the substrate and extending from the second surface to the first surface. The device also includes a conductive metal disposed in the opening and connected to the metal stack.

### BACKGROUND OF THE INVENTION

### Field of the Invention

The present disclosure relates to semiconductor structure, and, in particular, it relates to a semiconductor structure with a backside via.

### Description of the Related Art

Electronic components are integrally formed on a substrate. Such substrates typically include active devices and passive devices. Various factors make active devices different from passive devices, such as their functions, the nature of their energy, and their power gain. Active devices include transistors such as pseudomorphic high electron mobility transistors (pHEMT), metal-oxide semiconductor field effect transistors (MOSFETs), complementary metal-oxide semiconductor (CMOS) transistors, bipolar junction transistors (BJTs), laterally diffused MOS (LDMOS) transistors, high-voltage transistors, high-frequency transistors, and diodes. Passive devices include capacitors, resistors, and inductors.

Although existing semiconductor structures have generally been adequate for their intended purposes, they have not been entirely satisfactory in all respects, and need to be improved.

### BRIEF SUMMARY OF THE INVENTION

An embodiment of the present disclosure provides a semiconductor device including a substrate having a first surface and a second surface. The device also includes a metal stack disposed on the first surface. The metal stack includes a plurality of adhesion layers and at least one resistant layer alternately stacked. The device also includes an opening formed within the substrate and extending from the second surface to the first surface. The device also includes a conductive metal disposed in the opening and connected to the metal stack.

An embodiment of the present disclosure provides a semiconductor device. The device includes an epitaxial layer over a substrate. The device also includes an epitaxial layer over a substrate. The device also includes a gate structure over the epitaxial layer. The device also includes source/drain structures over opposite sides of the gate. The device also includes a field plate over the gate structures. The device also includes a metal stack comprising alternately stacked Ta layers and NiCr layers over the epitaxial layer. The device also includes conductive layers over the metal stack and the source/drain structures. The device also includes dielectric layers between the conductive layers. The device also includes a via structure through the substrate. The via structure is in direct contact with the metal stack.

In addition, an embodiment of the present disclosure provides a method of forming a semiconductor device. The method includes forming an epitaxial layer over a substrate. The method also includes depositing a first dielectric layer over the epitaxial layer. The method also includes forming a metal stack through the first dielectric layer. The metal stack includes alternately stacked Ta layers and NiCr layers over the epitaxial layer. The method also includes forming a first conductive layer over the metal stack. The method also includes forming a second dielectric layer over the first conductive layer. The method also includes patterning the second dielectric layer to form an opening exposing the first conductive layer. The method also includes forming a second conductive layer over the second dielectric layer.

### BRIEF DESCRIPTION OF THE DRAWINGS

The present disclosure can be more fully understood by reading the subsequent detailed description and examples with references made to the accompanying drawings, wherein:

FIG. 1 is a cross-sectional representation of a semiconductor structure in accordance with some embodiments.

FIG. 1A is an enlarged cross-sectional representation of a semiconductor structure in accordance with some embodiments.

FIG. 1B is an enlarged cross-sectional representation of a semiconductor structure in accordance with some embodiments.

FIG. 1C is an enlarged cross-sectional representation of a semiconductor structure in accordance with some embodiments.

FIG. 2 is an enlarged cross-sectional representation of a semiconductor structure in accordance with some embodiments.

FIG. 3 is a cross-sectional representation of a semiconductor structure in accordance with some embodiments.

### DETAILED DESCRIPTION OF THE INVENTION

The following disclosure provides many different embodiments, or examples, for implementing different features of the disclosure. Specific examples of components and arrangements are described below to simplify the present disclosure. These are, of course, merely examples and are not intended to be limiting. For example, the formation or the disposal of a first feature over or on a second feature in the description that follows may include embodiments in which the first and second features are formed in direct contact, and may also include embodiments in which additional feature(s) may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Herein, the terms “around,” “about,” “substantial” usually mean within 20% of a given value or range, such as within 10%, 5%, 3%, 2%, 1%, or 0.5%. It should be noted that the quantity herein is a substantial quantity, which means that the meaning of “around,” “about,” “substantial” are still implied even without specific mention of the terms “around,” “about,” “substantial.”

Although some embodiments are discussed with operations performed in a particular order, these operations may be performed in another logical order. In different embodiments, additional operations can be provided before, during, and/or after the stages described the present disclosure. Some of the stages that are described can be replaced or eliminated for different embodiments. Additional features can be added to the semiconductor structure in the present disclosure. Some of the features described below can be replaced or eliminated for different embodiments.

The present disclosure provides a semiconductor structure. The semiconductor structure includes a backside via structure. A metal stop layer is formed between the front-side metal and the backside via structure. The metal stop layer may decrease the over-etching of the front-side metal when forming the backside via structure. Therefore, the etching power may be enhanced and the etching process time may be reduced.

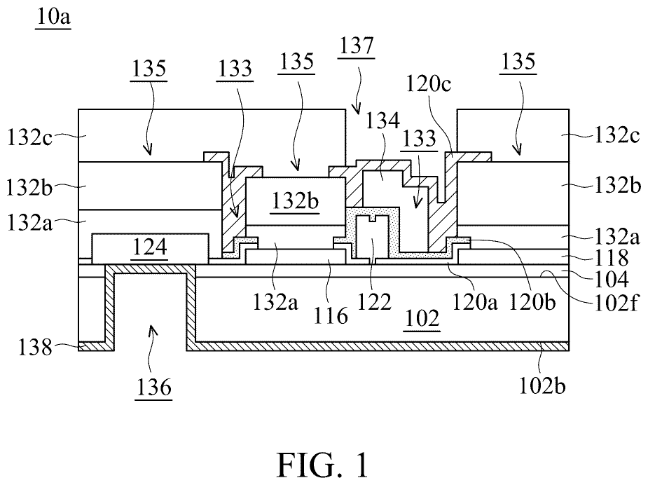

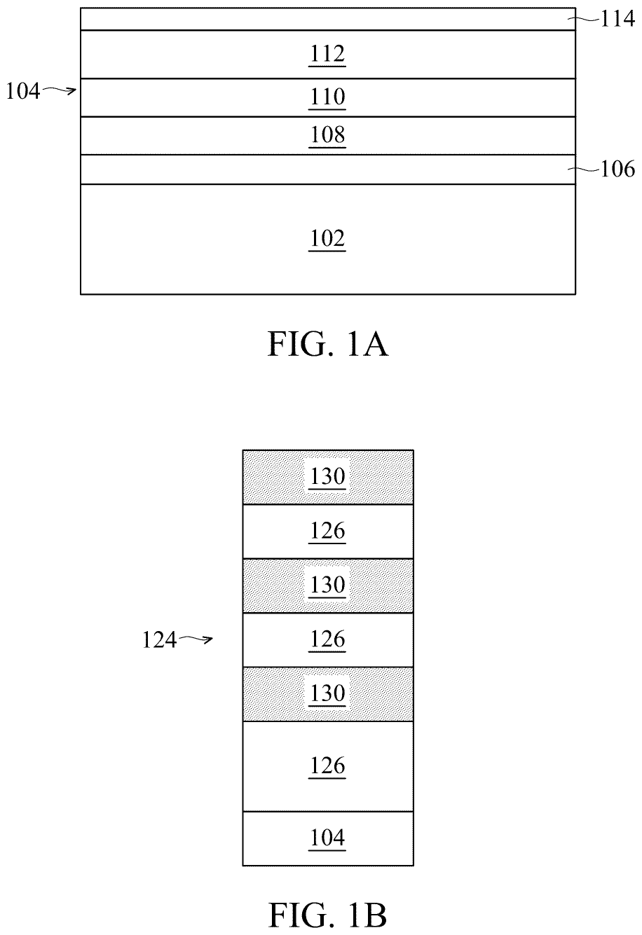

FIG. 1 is a cross-sectional representation of a semiconductor structure 10a in accordance with some embodiments. A substrate 102 is provided, as shown in FIG. 1 in accordance with some embodiments. The substrate 102 may be a semiconductor substrate, a glass substrate, a ceramic substrate, a sapphire substrate, semiconductor-on-insulator (SOI) substrate, or a combination thereof, but not limited thereto. The material of the substrate 102 may include III-V semiconductors such as GaN, AlGaN, AlN, GaAs, AlGaAs, InP, InAlAs, InGaAs, or a combination thereof, but not limited thereto, the material of the substrate 102 may include IV semiconductor, such as Si or Ge. The substrate 102 may include undoped or doped material. In some embodiments, the substrate 102 includes SiC. In some embodiments, the substrate 102 has a first surface 102f and a second surface 102b opposite to the first surface 102f. The first surface 102f may be referred to the frontside while the second surface may be referred to the backside, but not limited thereto. The following layers may be formed on the first surface 102f of the substrate 102.

An epitaxial layer 104 may be formed on the substrate 102, as shown in FIG. 1 in accordance with some embodiments. In some embodiments, the epitaxial layer 104 is a multi-layer structure. The epitaxial layer 104 may include Ga-face sub-layers or N-face sub-layers, but not limited thereto. FIG. 1A is an enlarged cross-sectional representation of the epitaxial layer 104 of the semiconductor structure 10a in accordance with some embodiments. In some embodiments, the epitaxial layer 104 may include a nucleation layer 106, a buffer layer 108, a channel layer 110, a carrier supply layer 112, and a cap layer 114.

In some embodiments, the buffer layer 108 may be formed on the nucleation layer 106, and the channel layer 110 may be formed on the buffer layer 108. The carrier supply layer 112 may be formed on the channel layer 110, and the cap layer 114 may be formed on the carrier supply layer 112, but not limited thereto. In other embodiments not illustrated in the drawings, the carrier supply layer may be formed on the buffer layer and the channel layer may be formed on the carrier supply layer when they are N-face, but not limited thereto. The material of the nucleation layer 106 may include GaAs, AlN, AlGaN or other suitable materials, but not limited thereto. The material of the buffer layer 108 may include at least one of GaAs, AlGaAs, GaN, AlGaN and other suitable materials, but not limited thereto. The material of the channel layer 110 may include at least one of GaAs, GaN, AlGaN, InGaAs and other suitable materials, but not limited thereto. The material of the carrier supply layer 112 may include at least one of AlGaAs, AlGaN, AlGaAsP, InAlGaAs, InGaP, InGaPAs, AlInGaP, or a combination thereof, but not limited thereto. The material of the cap layer 114 may include GaAs, GaN or other suitable materials, but not limited thereto. The nucleation layer 106, the buffer layer 108, the channel layer 110, the carrier supply layer 112, and the cap layer 114 may be formed by molecular-beam epitaxy (MBE), metalorganic chemical vapor deposition (MOCVD), hydride vapor phase epitaxy (HVPE), other suitable methods, or a combination thereof.

The band gaps of the channel layer 110 and the carrier supply layer 112 may be different. A heterojunction may be formed at the interface between the channel layer 110 and the carrier supply layer 112. The energy band may bend at the heterojunction, and a quantum well may be formed at the deep portion of the conduction band. The electrons produced by piezoelectric polarization or spontaneous polarization may be confined in the quantum well. Therefore, a two-dimensional electron gas (2DEG) may be formed at the interface between the channel layer and the carrier supply layer, and a conducting current may be formed by the 2DEG.

Next, a source electrode 116 and a drain electrode 118 are formed over the epitaxial layer 104, as shown in FIG. 1 in accordance with some embodiments. The source electrode 116 and the drain electrode 118 may respectively include Ti, Al, W, Au, Pd, Au, Ge, Ni, Mo, Pt, other applicable metals, their alloys, or a combination thereof, but not limited thereto. The source electrode 116 and the drain electrode 118 may be formed by a physical vapor deposition (PVD) process (such as resistive heating evaporation, e-beam evaporation, or sputtering), a chemical vapor deposition (CVD) process (such as a low-pressure chemical vapor deposition process (LPCVD) or a plasma enhanced chemical vapor deposition process (PECVD)), electroplating, atomic layer deposition (ALD), other suitable process, or a combination thereof. In some embodiments, the source electrode 116 and the drain electrode 118 are formed by an evaporation process.

Next, a first dielectric layer 120a may be formed on the source electrode 116 and the drain electrode 118, as shown in FIG. 1 in accordance with some embodiments. The first dielectric layer 120a may be single-layered or multi-layered. The first dielectric layer 120a may be made of silicon nitride, silicon oxide, aluminum nitride, aluminum oxide, other suitable insulating material, or a combination thereof, but not limited thereto. In some embodiments, the first dielectric layer 120a includes silicon nitride, silicon oxide, aluminum nitride, aluminum oxide, other suitable insulating material or a combination thereof, but not limited thereto. The first dielectric layer 120a may be formed by a deposition process. The deposition process may include a CVD process (such as LPCVD, PECVD, Sub-Atmospheric Pressure Chemical Vapor Deposition (SACVD), or flowable chemical vapor deposition (FCVD)), an ALD process, another applicable method, or a combination thereof.

Next, an opening is formed through the first dielectric layer 120a between the source electrode 116 and the drain electrode 118, as shown in FIG. 1 in accordance with some embodiments. The opening may be formed by a patterning process. The patterning process may include a photolithography process and an etching process. Examples of photolithography processes include photoresist coating, soft baking, mask aligning, exposure, post-exposure baking, developing the photoresist, rinsing and drying. The etching process may be a dry etching process, a wet etching process or a combination thereof. In some embodiments, the etching process may include a reactive-ion etching (RIE) using inductively coupled plasma (ICP) as etchant.

Next, a gate electrode 122 is formed in the opening and on the first dielectric layer 120a, as shown in FIG. 1 in accordance with some embodiments. The gate electrode 122 may include Mo, W, WSi, Ti, TiW, Ir, Pd, Pt, Ni, Co, Cr, Ru, Os, Rh, Ta, TaN, Al, Re, Au, other applicable conductive materials, or a combination thereof. The gate electrode 104 may be formed by a PVD process (such as resistive heating evaporation, e-beam evaporation, or sputtering), a CVD process (such as a low pressure chemical vapor deposition process or a plasma enhanced chemical vapor deposition process), electroplating, ALD, other suitable process, or a combination thereof. In some embodiments, the gate electrode 122 is formed by an evaporation process.

Next, a second dielectric layer 120b may be formed on the gate electrode 122, the source electrode 116, and the drain electrode 118, as shown in FIG. 1 in accordance with some embodiments. The second dielectric layer 120b may be single-layered or multi-layered. The second dielectric layer 120b may be made of silicon nitride, silicon oxide, aluminum oxide, other suitable insulating material, or a combination thereof. In some embodiments, the second dielectric layer 120b may include silicon nitride, silicon oxide, aluminum oxide, other suitable insulating material, or a combination thereof, but not limited thereto. The second dielectric layer 120b may be formed by a deposition process. The deposition process may include a CVD process (such as LPCVD, PECVD, SACVD, or FCVD), an ALD process, another applicable method, or a combination thereof.

Next, openings may be formed through the first dielectric layer 120a and the second dielectric layer 120b, as shown in FIG. 1 in accordance with some embodiments. The opening may be formed by a patterning process. The openings are formed over the source electrode 116 and the drain electrode 118, and beside the source electrode 116. In some embodiments, the source electrode 116 and the drain electrode 118, and the epitaxial layer 104 are exposed from the openings. The patterning process may include a photolithography process and an etching process. Examples of photolithography processes include photoresist coating, soft baking, mask aligning, exposure, post-exposure baking, developing the photoresist, rinsing and drying. The etching process may be a dry etching process, a wet etching process or a combination thereof. In some embodiments, the etching process is a reactive-ion etching (RIE) using inductively coupled plasma (ICP) as etchant.

Later, a metal stack 124 may be formed in at least one of the openings through the first dielectric layer 120a and the second dielectric layer 120b on the epitaxial layer 104, as shown in FIG. 1 in accordance with some embodiments. FIG. 1B is an enlarged cross-sectional representation of the metal stack 124 of the semiconductor structure 10a in accordance with some embodiments. In some embodiments, the metal stack 124 may include alternately stacked adhesion layers 126 and at least one resistant layer 130. The material of the adhesion layers 126 may include refractory metal, such as Nb, Mo, Ta, W, Re, but not limited thereto. The material of the resistant layer 130 may include nickel (Ni) and/or nickel alloy, but not limited thereto. In one example, the material of the resistant layer 130 may include Ni, Cr, an alloy including Ni, Cr, other suitable material or a combination thereof, but not limited thereto. For example, the resistant layer 130 may include a nichrome (NiCr) alloy, and the mole fraction of Ni in the NiCr may be ranged from 20% to 80% (20%≤Ni mol%≤85%), such as 35%, 50%, 60% or 80%, but not limited thereto. In some embodiments, the adhesion layers 126 may include Ta, and the resistant layer(s) 130 may include a NiCr alloy. The etching rate of the resistant layers 130 may be low, and the resistant layers 130 may be an etch stop for subsequently etching process. The adhesion layers 126 may eliminate the stress caused by the resistant layers 130. The adhesion layers 126 and the resistant layers 130 may be formed by atomic layer deposition (ALD), physical vapor deposition (PVD), chemical vapor deposition (CVD), or other suitable deposition methods.

It should be noted that, the thicknesses of the adhesion layers 126 and resistant layers 130 shown in FIG. 1B are merely an example, and not limited herein, depending on the demand of process. In some embodiments, the bottommost adhesion layer 126 may be in direct contact with the epitaxial layer 104. In some embodiments, the thickness of the resistant layers 130 may be greater than the thickness of the adhesion layers 126. In some embodiments, the ratio of the thickness of the resistant layers 130 to the thickness of the adhesion layers 126 may be in a range from about 3 to about 7(3≤ratio≤7), such as 4, 5 or 6. In some embodiments, the bottommost adhesion layer 126 may be thicker than one of the upper adhesion layers 126. For example, the bottommost adhesion layer 126 may be thicker than each of the upper adhesion layers 126, but not limited thereto. In some embodiments, the thickness of the resistant layers 130 may be less than about 1000 angstroms (thickness<1000 angstroms), such as 100 angstroms, 200 angstroms, 300 angstroms, 400 angstroms, 500 angstroms, 600 angstroms, 700 angstroms or 800 angstroms. In some embodiments, the thickness of the adhesion layer 126 may be less than about 500 angstroms. If the adhesion layer 126 and the resistant layers 130 are too thick, the metal stack 124 may be peeled.

It should be noted that, although there are three layers of the adhesion layer 126 and three layers of the resistant layers 130 shown in FIG. 1B, the number of the adhesion layers 126 and the resistant layers 130 are not limited herein, depending on the demand of performance and process. The uppermost layer of the metal stack 124 may be the adhesion layer 126 or the resistant layer 130. For example, the metal stack 124 may include a plurality of the adhesion layers 126 and at least one resistant layer 130. The number of the plurality of the adhesion layers 126 may be in a range from 2 to 8(2≤No.≤8), such as 3, 4, 5, 6 or 7, but not limited thereto. The number of the at least one resistant layers 130 may be in a range from 1 to 8(1≤No.≤8), such as 2, 3, 4, 5, 6 or 7, but not limited thereto. In a specific example, the metal stack 124 may include two adhesion layers 126 and one resistant layer 130.

Next, a first metal layer 132a may be formed on the metal stack 124, the source electrode 116, and the drain electrode 118, as shown in FIG. 1 in accordance with some embodiments. In some embodiments, the first metal layer 132a may be in direct contact with the topmost layer of the metal stack 124, such as the resistant layer 130. In some embodiments, the first metal layer 132a may cover the top surface and sidewalls of the metal stack 124. The term “cover” may include “fully cover” and “partially cover”.

The material of the first metal layer 132a may include Au, Ti, Pt, Ni, Cu, other suitable materials, or a combination thereof. The first metal layer 132a may be formed by electroplating, e-beam evaporation, resistive heating evaporation, sputtering, physical vapor deposition (PVD), chemical vapor deposition (CVD), atomic layer deposition (ALD), another suitable method, or a combination thereof. In some embodiments, the first metal layer 132a may be a single-layer or a multi-layer structure.

Next, a second metal layer 132b may be formed on the first metal layer 132a, as shown in FIG. 1 in accordance with some embodiments. The second metal layer 132b may include Au, Ti, Ni, Pt, Cu, other suitable materials, or a combination thereof. The second metal layer 132b may be formed by electroplating, e-beam evaporation, resistive heating evaporation, sputtering, physical vapor deposition (PVD), chemical vapor deposition (CVD), atomic layer deposition (ALD), another suitable method, or a combination thereof.

Later, trenches 133 may be formed over the gate electrode 120 and between the source electrode 116 and the metal stack 124. The second dielectric layer 120b is exposed from the trenches 133. The trenches 133 may be formed by a patterning process. The patterning process may include a photolithography process and an etching process. Examples of photolithography processes include photoresist coating, soft baking, mask aligning, exposure, post-exposure baking, developing the photoresist, rinsing and drying. The etching process may include a dry etching process, a wet etching process or a combination thereof.

Next, a field plate 134 is formed over the gate electrode 122, as shown in FIG. 1 in accordance with some embodiments. The field plate 134 may include Cu, W, Ag, Sn, Ni, Co, Cr, Ti, Pb, Au, Bi, Sb, Zn, Zr, Mg, In, Te, Ga, other applicable metallic materials, an alloy thereof, or a combination thereof. The field plate 134 may be a single-layered or a multi-layered structure.

Next, a third dielectric layer 120c may be formed on the field plate 134 and in the trenches, as shown in FIG. 1 in accordance with some embodiments. The third dielectric layer 120c may include silicon nitride, silicon oxide, aluminum oxide, other suitable insulating material, or a combination thereof.

Next, openings 135 may be formed through the third dielectric layer 120c, as shown in FIG. 1 in accordance with some embodiments. The opening 135 may be formed by a patterning process. The openings 135 are formed on the second metal layer 132b which is formed on the source electrode 116, the drain electrode 118, and/or the metal stack 124. In some embodiments, the second metal layer 132b disposed on the source electrode 116, the drain electrode 118, and/or the metal stack 124 are exposed from the openings 135.

Next, a third metal layer 132c may be formed on the second metal layer 132b, as shown in FIG. 1 in accordance with some embodiments. The third metal layer 132c may include Au, Ti, Ni, Pt, Cu, other suitable materials, or a combination thereof. The third metal layer 132c may be formed by electroplating, e-beam evaporation, resistive heating evaporation, sputtering, physical vapor deposition (PVD), chemical vapor deposition (CVD), atomic layer deposition (ALD), another suitable method, or a combination thereof.

Next, a trench 137 may be formed through the third metal layer 132c, as shown in FIG. 1 in accordance with some embodiments. The third dielectric layer 120c on the gate electrode 122 and the field plate 134 may be exposed from the trench 137.

Next, the semiconductor structure 10a may be flipped. FIG. 1C is an enlarged cross-sectional representation of the semiconductor structure 10a in accordance with some embodiments. The backside of the substrate 102 may be facing up, and the frontside of the substrate 102 may be facing down. The frontside of the substrate 102 may be covered by a protection layer (not shown) before being flipped, but not limited thereto. The first metal layer 132a may include a first layer 132a1 in direct contact to the metal stack 124, a second layer 132a2 on the first layer 132a1, and a third layer 132a3 on the second layer 132a2.

In some embodiments, the third layer 132a3 may be thicker than each of the first layer 132a1 and the second layer 132a2. In some embodiments, the thicknesses of the first layer 132a1 and the second layer 132a2 may be substantially the same, but not limited thereto.

A planarization may be performed on the backside of the substrate 102. The planarization may be used for thinning the substrate 102. The substrate 102 in FIG. 1 is a planarized substrate. The planarization step may be performed in different sequences as different embodiments. For example, the planarization step may be performed before the growth of the epitaxial layer 104, after the formation of the first metal layer 132, or after the formation of the third dielectric layer 120c, but not limited thereto. The planarization process may include an etching process, a CMP process, a mechanical grinding process, a dry polishing process, or a combination thereof.

Further, a backside opening 136 may be formed through the planarized substrate 102 and the epitaxial layer 104 from the second surface 102b to the first surface 102f of the planarized substrate 102, as shown in FIGS. 1 and 1C in accordance with some embodiments. The metal stack 124 is exposed from the backside opening 136. The backside opening 136 may be formed by a patterning process. The patterning process may include a photolithography process and an etching process. A hard mask may be used in the patterning process. In some embodiments, the hard mask may include metal, such as Ni. The etching process may be a dry etching process, a wet etching process or a combination thereof. In some embodiments, the etching process is an Inductively Coupled Plasma (ICP) etching process. After the etching process, the hard mask may be removed.

In some embodiments, the sidewalls of the backside opening 136 in the substrate 102 may be substantially vertical, and the sidewalls of the backside opening 136 in the epitaxial layer 104 may be tapered, but not limited thereto. In some embodiments, the bottom of the backside opening 136 is narrower than the top of the backside opening 136. Here, the bottom of the backside opening 136 is close to the metal stack 124.

With the resistant layer(s) 130 in the metal stack 124, the metal stack 124 may not be etched through during the etching process of forming the backside opening 136. Therefore, the etching power may be enhanced, and the etching process time may be reduced.

Next, a metal structure 138 may be formed in the backside opening 136, as shown in FIG. 1 in accordance with some embodiments. The metal structure 138 may be a via structure. The metal structure 138 may be formed through the substrate 102.

In some embodiments, the metal structure 138 may be connected to the metal stack 124. In some embodiments, the metal structure 138 is in direct contact with the metal stack 124. In some embodiments, the metal structure 138 is in direct contact with the resistant layer 130 of the metal stack.

The metal structure 138 may include conductive metal. The metal structure 138 may include Au, Ti, Ni, Pt, Cu, other suitable materials, or a combination thereof. In some embodiments, the metal structure 138 includes Au. The metal structure 138 may be formed by electroplating, e-beam evaporation, resistive heating evaporation, sputtering, physical vapor deposition (PVD), chemical vapor deposition (CVD), atomic layer deposition (ALD), another suitable method, or a combination thereof.

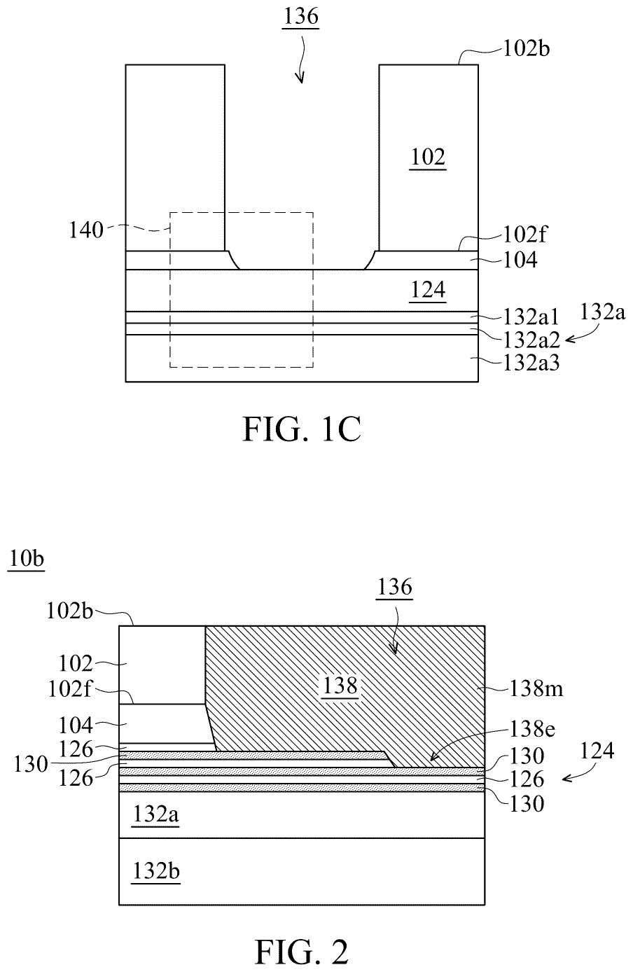

Many variations and/or modifications may be made to the embodiments of the disclosure. FIG. 2 is an enlarged cross-sectional representation of a semiconductor structure 10b in accordance with some embodiments. Some processes or devices are the same as, or similar to, those described in the embodiments above, and therefore the descriptions of these processes and devices are not repeated herein. The difference from the embodiments described above is that, as shown in FIG. 2 in accordance with some other embodiments, the metal stack 124 may be partially consumed during the etching process of forming the backside opening 136.

FIG. 2 is an enlarged cross-sectional representation of a dashed box 140 shown in FIG. 1C. In some embodiments, some layers of the metal stack 124 are etched during the etching process forming the backside opening 136. With the resistant layers 130, some of the resistant layers 130 and the adhesion layers 126 remain during the etching process, and thus the first metal layer 132a may not be damaged.

In some embodiments, a portion of the metal stack 124 may surround an extending portion 138e of the metal structure 138. The extending portion 138e may be referred to the portion of the metal structure 138 in the backside opening 136 of the metal stack 124. In some embodiments, the extending portion 138e of the metal structure 138 is narrower than the main portion 138m of the metal structure 138 corresponding to the substrate 102 and/or the epitaxial layer 104.

In some embodiments, there are at least three layers of the resistant layers 130 and the adhesion layers 126 remain after the etching process. In some embodiments, the etched resistant layers 130 and the adhesion layers 126 may have tapered sidewalls in the backside opening 136. In some embodiments, the metal structure 138 is in direct contact with the resistant layer(s) 130 and the adhesion layer(s) 126.

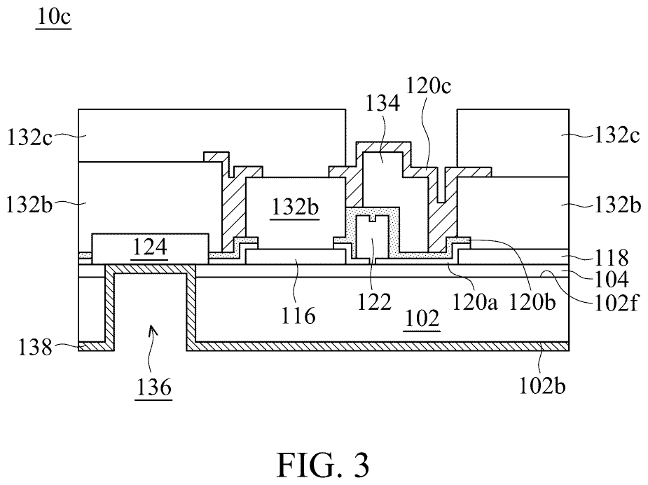

Many variations and/or modifications may be made to the embodiments of the disclosure. FIG. 3 is a cross-sectional representation of a semiconductor structure 10c in accordance with some embodiments. Some processes or devices are the same as, or similar to, those described in the embodiments above, and therefore the descriptions of these processes and devices are not repeated herein. The difference from the embodiments described above is that, as shown in FIG. 3 in accordance with some other embodiments, the second metal layer 132b is directly formed on the metal stack 124.

In some embodiments, the second metal layer 132b is in direct contact with the metal stack 124, the source electrode 116, and the drain electrode 118. The second metal layer 132b may be disposed on the second dielectric layer 120b. The process time and cost may be reduced.

As mentioned above, in the present disclosure, a semiconductor structure and a method of forming a semiconductor structure are provided. With resistant layers and adhesion layers alternatively formed corresponding to the backside opening, the etching process of the backside opening may not damage the metal layer on the frontside of the substrate. The power of etching process may be enhanced, and the etching process time may be reduced.

It should be noted that although some of the benefits and effects are described in the embodiments above, not every embodiment needs to achieve all the benefits and effects.

The foregoing outlines features of several embodiments so that those skilled in the art may better understand the aspects of the present disclosure. The features of the embodiments mentioned above may be mixed, recombined or restructured to construct another embodiment of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate having a first surface and a second surface;
a metal stack disposed on the first surface and comprising a plurality of adhesion layers and at least one resistant layer alternately stacked;
an opening formed within the substrate and extending from the second surface to the first surface; and
a conductive metal disposed in the opening and connected to the metal stack.

2. The semiconductor device as claimed in claim 1, wherein the plurality of adhesion layers comprise refractory metal.

3. The semiconductor device as claimed in claim 1, wherein the plurality of adhesion layers comprise Ta.

4. The semiconductor device as claimed in claim 1, wherein the at least one resistant layer comprises nichrome.

5. The semiconductor device as claimed in claim 1, wherein a thickness of one of the at least one resistant layer is greater than a thickness of one of the plurality of adhesion layers.

6. The semiconductor device as claimed in claim 1, wherein a ratio of a thickness of one of the at least one resistant layer to a thickness of one of the plurality of adhesion layers is in a range from about 3 to about 7.

7. The semiconductor device as claimed in claim 1, wherein a thickness of one of the at least one resistant layer is less than about 1000 angstroms.

8. The semiconductor device as claimed in claim 1, wherein the conductive metal is in direct contact with one of the at least one resistant layer.

9. The semiconductor device as claimed in claim 1, wherein a portion of the metal stack surrounds an extending portion of the conductive metal.

10. The semiconductor device as claimed in claim 9, wherein the extending portion of the conductive metal is narrower than a main portion of the conductive metal.

11. The semiconductor device as claimed in claim 1, wherein a number of the plurality of adhesion layers is in a range from 3 to 8, and a number of the at least one resistant layer is in a range from 3 to 8.

12. A semiconductor device, comprising:
an epitaxial layer disposed on a substrate;
a gate structure disposed on the epitaxial layer;
source/drain structures on opposite sides of the gate structure;
a field plate over the gate structures;
a metal stack disposed on the epitaxial layer and comprising alternately stacked Ta layers and nichrome layers;
a metal layer disposed on the metal stack and the source/drain structures; and
a via structure through the substrate,
wherein the via structure is in direct contact with the metal stack.

13. The semiconductor device as claimed in claim 12, wherein the epitaxial layer is in direct contact with one of the Ta layers of the metal stack.

14. The semiconductor device as claimed in claim 12, wherein a bottommost Ta layer of the metal stack is thicker than one of other Ta layers of the metal stack.

15. The semiconductor device as claimed in claim 12, wherein the metal layer is in direct contact with the nichrome layer of the metal stack.

16. The semiconductor device as claimed in claim 12, wherein the metal layer covers a top surface and sidewalls of the metal stack.

17. A method of forming a semiconductor device, comprising:
forming an epitaxial layer over a substrate;
depositing a first dielectric layer over the epitaxial layer;
forming a metal stack through the first dielectric layer, wherein the metal stack comprises alternately stacked Ta layers and nichrome layers over the epitaxial layer;
forming a first conductive layer over the metal stack;
forming a second dielectric layer over the first conductive layer;
patterning the second dielectric layer to form an opening exposing the first conductive layer; and
forming a second conductive layer over the second dielectric layer.

18. The method as claimed in claim 17, further comprising:
forming a third conductive layer over the metal stack before forming the first conductive layer.

19. The method as claimed in claim 17, further comprising:
forming source/drain structures over the epitaxial layer before depositing the first dielectric layer; and
forming a gate structure over the first dielectric layer.

20. The method as claimed in claim 17, further comprising:
forming an opening through the substrate and exposing the metal stack; and
filling a conductive metal into the opening.
